(19) United States
(12) Patent Application Publication
(10) Pub. No.: US 2025/0338715 A1
(43) Pub. Date: Oct. 30, 2025

(54) DISPLAY PANEL AND DISPLAY DEVICE

(71) Applicant: HKC CORPORATION LIMITED, Shenzhen (CN)

(72) Inventors: Jing LI, Shenzhen (CN); Lidan YE, Shenzhen (CN)

(21) Appl. No.: 19/184,347

(22) Filed: Apr. 21, 2025

(30) Foreign Application Priority Data
Apr. 29, 2024 (CN) 202410533722.7

(51) Int. Cl. H10K 59/121; H10K 59/95

(52) U.S. Cl. CPC H10K 59/121; H10K 59/95

(57) ABSTRACT

A display panel includes a normal display region and a photosensitive display region corresponding to a photosensitive element, the normal display region is provided around the photosensitive display region, and includes a plurality of pixel units arranged in an array, and each pixel unit includes a plurality of display sub-pixels; the photosensitive display region includes a display pixel region and a light transmissive region, and the light transmissive region is arranged at intervals with the display pixel region; the display pixel region includes a first region and a second region, the light transmissive region is provided at a periphery of the first region and a periphery of the second region, and the first region and the second region are spaced apart in a row direction sequentially.

### CROSS-REFERENCE TO RELATED APPLICATIONS

This application claims priority to Chinese Patent Application No. 202410533722.7, filed on Apr. 29, 2024, the entire disclosure of which is hereby incorporated herein by reference.

### TECHNICAL FIELD

The present application belongs to the field of display technology, and specifically relates to a display panel and a display device.

### BACKGROUND

Due to the impact of the front camera, various shapes of screens, including bangs screen, water drop screen, dug hole screen, are mainly used in the current market, these anisotropic structures affect the aesthetics of the screens to a certain extent. A phone with a lifting camera or a slider phone can realize the real full screen, and the lifting camera and the slider camera do not only cost much, but also have great difficulty in designing the mechanism, and their abilities to withstand the fall needs to be dramatically improved. Therefore, the under-screen camera is the optimal solution for full-screen, taking into account the cost and performance.

However, the existing under-screen camera has poor imaging effect and other problems.

### SUMMARY

There are provided a display panel and a display device capable of improving the imaging effect of the photosensitive element in the display panel according to embodiments of the present disclosure. The technical solution is as below:

A first aspect of the present application provides a display panel, which includes:
a normal display region and a photosensitive display region corresponding to a photosensitive element, the normal display region is provided around the photosensitive display region, the normal display region includes a plurality of pixel units arranged in an array, and each pixel unit includes a plurality of display sub-pixels;
the photosensitive display region includes a display pixel region and a light transmissive region, and the light transmissive region is arranged at intervals with the display pixel region;
the display pixel region includes a first region and a second region, the light transmissive region is provided at a periphery of the first region and a periphery of the second region, and the first region and the second region are spaced apart in a row direction sequentially; and
pixels in at least one of the first region and the second region are arranged in the same way as display sub-pixels in each of the plurality of pixel units in the normal display region.

A second aspect of the present application provides a display device, which includes the display panel and the photosensitive element according to any one of the display devices as mentioned above, the photosensitive element corresponds to the photosensitive display region.

It should be understood that the above general description and the detailed description that follows are merely exemplary and explanatory, and do not limit the present application.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. It will be apparent that the accompanying drawings in the following description are only some of the embodiments of the present application, and that other accompanying drawings may be obtained from these drawings without creative labor for those skilled in the art.

FIG. 1 is a schematic structural view of a normal display region and a photosensitive display region provided in a first embodiment, a second embodiment, a third embodiment, a fourth embodiment, or a fifth embodiment of the present application.

FIG. 2 is a schematic structural view of the arrangement of pixel units in the normal display region provided by the first embodiment, the second embodiment, the third embodiment, the fourth embodiment, or the fifth embodiment of the present application.

FIG. 3 is a schematic structural view of a light transmissive region and a display pixel region provided by the first embodiment, the second embodiment, the third embodiment, the fourth embodiment, or the fifth embodiment of the present application.

FIG. 4 is a schematic structural view of a photosensitive display region provided by the first embodiment or the fifth embodiment of the present application.

FIG. 5 is a schematic structural view of the light transmissive region and the first region provided in the first embodiment or the fifth embodiment of the present application.

FIG. 6 is a schematic structural view of the light transmissive region provided with a first circular region and a second circular region provided in the second embodiment or the fifth embodiment of the present application.

FIG. 7 is a schematic structural view of the first region provided with a first circular region and a second circular region provided in the second embodiment or the fifth embodiment of the present application.

FIG. 8 is a schematic structural view of a third straight edge provided with a first partition and a fourth straight edge provided with a second partition provided by the third embodiment or the fifth embodiment of the present application.

FIG. 9 is a partially enlarged structural view of the third straight edge provided with the first partition and the fourth straight edge provided with the second partition provided by the third embodiment or the fifth embodiment of the present application.

FIG. 10 is a schematic structural view of the first circular region and the second circular region provided with a connection region provided by the fourth embodiment or the fifth embodiment of the present application.

FIG. 11 is an enlarged schematic structural view of the first circular region and the second circular region connected by the connection region provided by the fourth embodiment or the fifth embodiment of the present application.

### DETAILED DESCRIPTION OF THE EMBODIMENTS

Embodiments will now be described more fully with reference to the accompanying drawings. However, the embodiments are capable of being implemented in a variety of forms and should not be construed as limitation to the examples set forth herein; rather, the provision of these embodiments makes the present application more comprehensive and complete and conveys the idea of the embodiments in a comprehensive manner to those skilled in the art.

In the present application, the terms “first” and “second” are used for descriptive purposes only and are not to be construed as indicating or implying relative importance or implicitly specifying the number of technical features indicated. As a result, a feature defined with the terms “first” and “second” may expressly or implicitly include one or more such features. In the description of the present application, “more than one” means two or more, unless otherwise expressly and specifically limited.

In the present application, unless otherwise expressly specified and limited, the terms “assembly”, “connection”, etc. are to be broadly understood, e.g., as a fixed connection, a detachable connection, formed integratedly, a mechanical connection, or an electrical connection, or a direct connection or an indirect connection through an intermediate medium, a communication within two elements or an interaction between two elements. For those skilled in the art, the specific meanings of the above terms in the present application may be understood based on actual situations.

In addition, the described features, structures, or characteristics may be combined in one or more embodiments in any suitable manner. In the following description, many specific details are provided thereby giving a full understanding of the embodiments of the present application. However, those skilled in the art will realize that it is possible to practice the technical embodiments of the present application without one or more of the specific details, or that other methods, components, devices, steps, etc. may be employed. In other cases, the well-known methods, devices, implementations, or operations are not shown or described in detail to avoid blurring aspects of the present application.

### First Embodiment

The first Embodiment of the present application provides a display panel 10, the display panel 10 may be an Organic Light Emitting Diode (OLED) display, or other types of display panels 10, for example, a Micro Light Emitting Diode (micro LED).

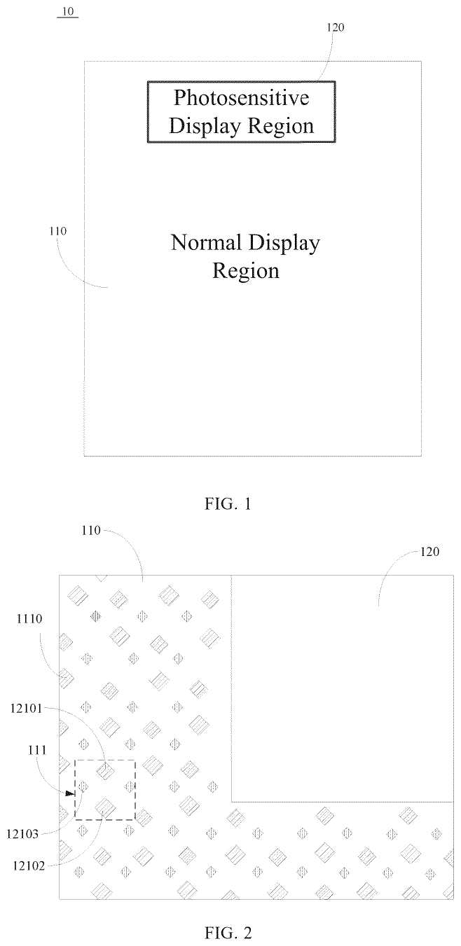

Referring to FIG. 1 or FIG. 2, the display panel 10 includes a normal display region 110. The normal display region 110 is configured to display a normal screen, and the normal display region 110 includes a plurality of pixel units 111 arranged in an array, and each pixel unit 111 includes a plurality of display sub-pixels 1110 of different colors, such as, a red display sub-pixel 12101, a green display sub-pixel 12103 and a blue display sub-pixel 12102, etc. The plurality of display sub-pixels 1110 of different colors may be spaced apart in the row direction, or may be arranged in other ways, which may be designed according to different embodiments.

Exemplarily, a pixel unit 111 includes a red display sub-pixel 12101, a blue display sub-pixel 12102, and two green display sub-pixels 12103. The red display sub-pixel 12101 and the blue display sub-pixel 12102 are sequentially arranged in a column direction. The two green display sub-pixels 12103 are spaced apart in the row direction, and located in the row direction between the red display sub-pixel 12101 and the blue display sub-pixel 12102. A connection pattern of the red display sub-pixel 12101, the blue display sub-pixel 12102 and the two green display sub-pixels 12103 is of a diamond-shaped structure.

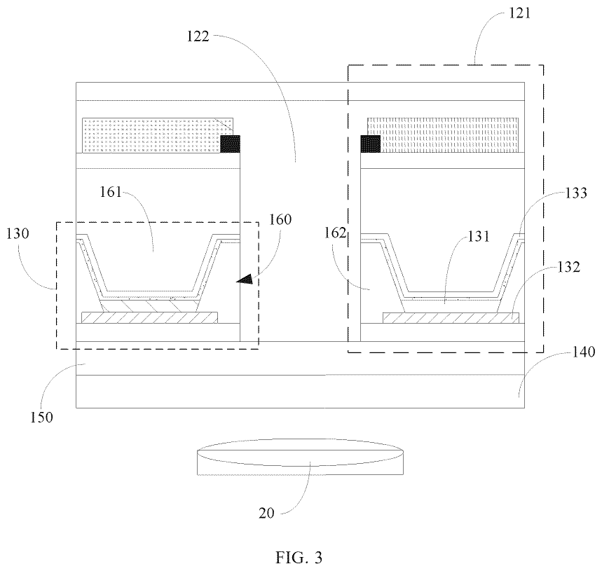

It is to be understood that as shown in FIG. 3, each display sub-pixel 1110 includes a display light emitting diode 130, and the display light emitting diode 130 includes a display light emitting portion 131 formed on the organic light emitting function layer. Each display light emitting portion 131 emits light of different colors, for example, emitting red light, green light, and blue light. Which color light is emitted means the display sub-pixel 1110 of corresponding color, i.e., if the red light is emitted, the display light emitting portion 131 is the red display sub-pixel 12101, if the green light is emitted, the display light emitting portion 131 is the green display sub-pixel 12103, and if the blue light is emitted, the display light emitting portion 131 is the blue display sub-pixel 12102.

In an embodiment of the present application, as shown in FIG. 3, the display panel 10 includes a substrate 140, and a driving circuit layer 150, a flattening layer and a pixel definition layer 160 formed sequentially on the substrate 140.

It is to be understood that the substrate 140 may be a rigid substrate 140 made of glass, but is not limited to this, or may also be a flexible substrate 140 made of a material such as polyimide (PI), i.e., the display device 1 of the present application is not limited to being a rigid non-bendable panel, but may also be a flexible bendable panel.

In addition, the driving circuit layer 150 may include circuit structures such as thin film transistors and metal-routing for driving the light emitting diodes mentioned later to emit light, which will not be repeated herein. The flattening layer is provided on a side of the driving circuit layer 150 away from the substrate 140 to flatten the driving circuit layer 150 for arranging the light emitting diodes mentioned later, so that the light emitting diodes of the entire display panel 10 are in the same plane to ensure the display effect.

As shown in FIG. 3, the pixel definition layer 160 may have a plurality of pixel openings 161 spaced apart, and a pixel definition portion 162 provided between adjacent pixel openings 161. In other words, the pixel definition layer 160 as a whole may be viewed as a grid-shaped skeletonized structural layer. The hollowed-out region is the pixel opening 161 for forming pixels of the present embodiment, and the non-hollowed-out region is the pixel definition portion 162 of the present embodiment. It should be understood that a surface of the pixel definition portion 162 away from the substrate 140 is plane. For example, the pixel definition layer 160 may be made of a material such as PI.

Furthermore, as shown in FIG. 3, the above display light emitting diode 130 further includes a display anode 132 and a display cathode 133, the display anode 132 is provided on a side of the display light emitting portion 131 close to the substrate 140, and the display cathode 133 is provided on a side of the display light emitting portion 131 away from the substrate 140.

It should be understood that the display anodes 132 of display light emitting diodes 130 in the display panel 10 are spaced apart from each other to be able to make each display light emitting diode 130 to be driven independently of each other, and the display cathodes 133 of display light emitting diodes 130 may be connected to each other to form electrodes in the same plane to reduce processing costs.

The display anode 132 may include a first conductive layer formed on a side of the flattening layer away from the driving circuit layer 150 and located between the flattening layer and the pixel definition layer 160, i.e., when fabricating the display panel 10, the first conductive layer is formed on the flattening layer first, and then the pixel definition layer 160 is fabricated. The pixel definition portion 162 covers an edge region of the first conductive layer, and the edge region of the first conductive layer may be connected to structures such as a thin film transistor in the driving circuit layer 150. The pixel opening 161 exposes a middle region of the first conductive layer, and the display light emitting portion 131 is provided within the pixel opening 161 and is in contact with the middle region of the first conductive layer.

For example, the first conductive layer may be a multilayer structure, i.e., the first conductive layer may include at least a reflective layer and a high power function material layer stacked sequentially. The high power function material layer may include indium tin oxide (ITO), indium zinc oxide (IZO), zinc oxide (ZnO), or indium oxide (In₂O₃). The reflective layer may include silver (Ag), i.e., the first conductive layer may be a ITO-Ag multilayer structure, but is not limited thereto. The first conductive layer may also include the high power function material layer, the reflective layer, and the high power function material layer stacked sequentially. For example, the first conductive layer may also be an ITO-Ag-ITO multilayer structure.

The display light emitting portion 131 may be provided within the pixel opening 161, i.e., when fabricating the display panel 10, the pixel definition layer 160 may be fabricated first, and then the display light emitting portion 131 may be fabricated, so that the display light emitting portion 131 is formed within the pixel opening 161. For example, the display light emitting portion 131 may be formed within the pixel opening 161 by vaporization, etc.

It is to be understood that the number of the display light emitting portions 131 is the same as the number of the pixel openings 161 and they correspond to each other one-in-one.

It should be understood that the display light emitting portion 131 may include a hole injection layer, a hole transmission layer, an organic light emitting material layer, an electron transmission layer, and an electron injection layer stacked sequentially. The hole injection layer is in contact with the display anode 132, and the electron injection layer is in contact with the display cathode 133, but is not limited to this. The display light emitting portion 131 may also include only the hole transmission layer, the light emitting material layer, and the electron transmission layer, or other structures, which is determined based on actual situations.

The display cathode 133 may be formed after the display light emitting portion 131 is formed and is in contact with the display light emitting portion 131. The display cathode 133 may include a low power function material layer, which includes Li, Ca, LiF and Ca, LiF and Al, Al, Mg, Ag, Pt, Pd, Ni, Au, Nd, Ir, Cr, BaF2, Ba, compounds thereof, or mixtures thereof, e.g., the display cathode 133 may include the low power function material layer made of a mixture of Ag and Mg.

It is worth mentioning that the display cathode 133 in the normal display region 110 and the display cathode 133 in the photosensitive display region 120 may be designed in the same plane, or the display cathodes 133 of the two regions may be separated from each other, i.e., separately designed, and connected by a metal-routing method.

Referring to FIGS. 1 and 2, the display panel 10 further includes a photosensitive display region 120 corresponding to the photosensitive element 20. The photosensitive display region 120 is surrounded by the normal display region 110. The photosensitive display region 120 includes a plurality of display pixel regions 121 and light transmissive regions 122, and the light transmissive region 122 is provided between adjacent display pixel regions 121. The light transmissive region 122 is spaced apart from the display pixel region 121, and a black region is provided between the light transmissive region 122 and the display pixel region 121. The black region is a metal-routing region or a shield layer for shielding the metal-routing region, and the shield layer may be a black matrix (BM), etc.

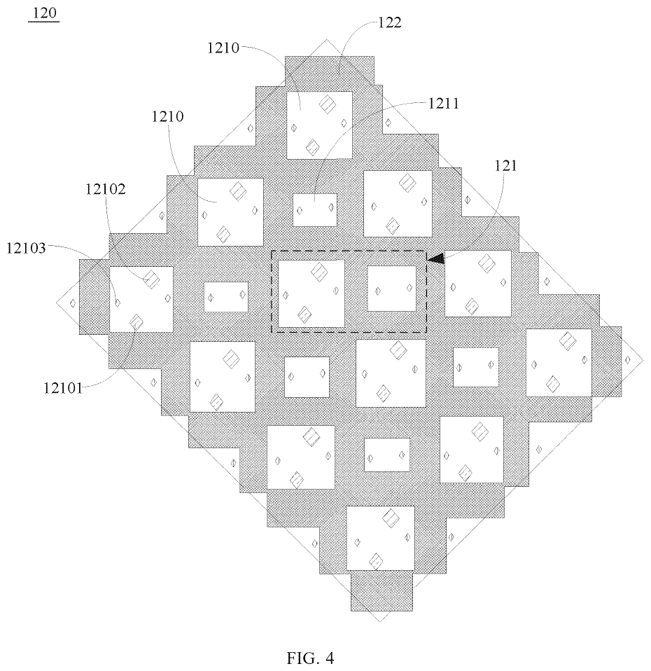

Referring to FIG. 4, the display pixel region 121 includes a first region 1210 and a second region 1211 spaced apart from each other, and the above light transmissive region 122 is provided at a periphery of the first region 1210 and a periphery of the second region 1211. It is also to be understood that the light transmissive region 122 encloses the first region 1210 and the second region 1211.

As shown in FIG. 4, the first region 1210 and the second region 1211 are sequentially spaced apart in the row direction, and the display pixel regions 121 in adjacent rows are interlaced. That is, the first region 1210 and the second region 1211 of the display pixel region 121 are provided in the same column as the second region 1211 and the first region 1210 of the display pixel region 121 in an adjacent row. The top, bottom, right and left sides of the second region 1211 are surrounded by different first regions 1210, respectively, and the light transmissive region 122 is provided between the first region 1210 and the second region 1211.

Pixels in at least one of the first region 1210 and the second region 1211 are arranged in the same way as the display sub-pixels 1110 in the pixel units 111 in the normal display region 110. That is, it may be that pixels in the first region 1210 are arranged in the same way as the display sub-pixels 1110 in the pixel units 111 in the normal display region 110, or may also be that the pixels in the second region 1211 are arranged in the same way same as the display sub-pixels 1110 in the pixel units 111 in the normal display region 110, or may be that the pixels in the first region 1210 and the second region 1211 are arranged in the same way as the display sub-pixels 1110 in the pixel units 111 in the normal display region 110.

Since the pixels in the first region 1210 and/or the second region 1211 are arranged in the same way as the display sub-pixels 1110 in the normal display region 110, the number of sub-pixels in the photosensitive display region 120 can be improved, thereby increasing the density of the sub-pixels in the photosensitive display region 120, and then increasing pixels per inch (PPI) of the photosensitive display region 120, and further improving display effect of the photosensitive display region 120. In addition, the transmissive region 122 can ensure the transmissive rate of the photosensitive display region 120. In other words, the number of the pixels in the photosensitive display region 120 is increased and the pixel structure in the photosensitive display region 120 is optimized under ensuring a high transmissive rate, the PPI of the display panel can be improved.

In an embodiment of the present application, as shown in FIGS. 2, 4, and 5, the pixels in the first region 1210 are arranged in the same way as the display sub-pixels 1110 in the pixel unit 111 in the normal display region 110, and the sub-pixels in the second region 1211 emit the same color. The first region 1210 and the second region 1211 can optimize the pixel structure in the photosensitive display region 120, thereby increasing the PPI of the photosensitive display region 120, and then improving the display effect of the display panel 10.

It is to be understood that since pixels in the first region 1210 are arranged in the same way as the display sub-pixels 1110 in the pixel units 111 in the normal display region 110, it is possible to make the display effects of the photosensitive display region 120 and the normal display region 110 balanced, thereby reducing the color difference therebetween. In addition, while ensuring the light transmission rate of the photosensitive display region 120, since the pixel structures in the first region 1210 and the second region 1211, compared to the original photosensitive display region 120, reduce the design size of the sub-pixels in the original photosensitive display region 120, the arrangement density of the sub-pixels in the photosensitive display region 120 is increased, and then the PPI of the photosensitive display region 120 is improved.

It is worth mentioning that there may also be only one first region 1210 in the display pixel region 121, and the first region 1210 can reduce the design size of the original sub-pixels, so as to increase the number of the sub-pixels per inch in the photosensitive display region 120, thereby increasing the arrangement density of the sub-pixels in the photosensitive display region 120, such that a problem of a heavy sense of grains in the photosensitive display region 120 is solved.

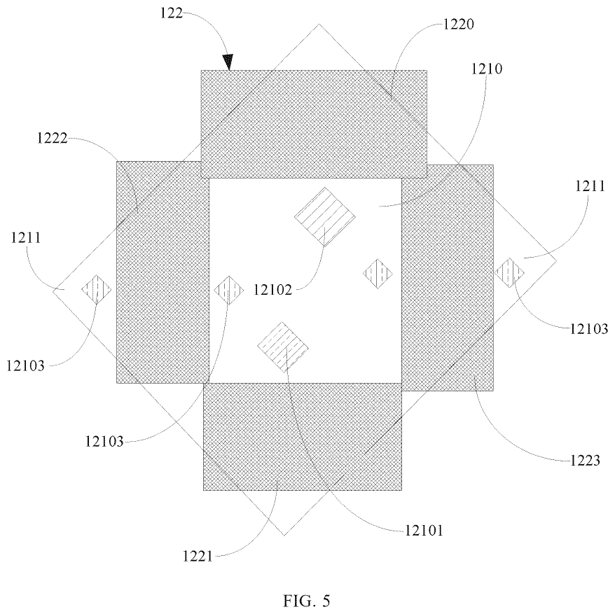

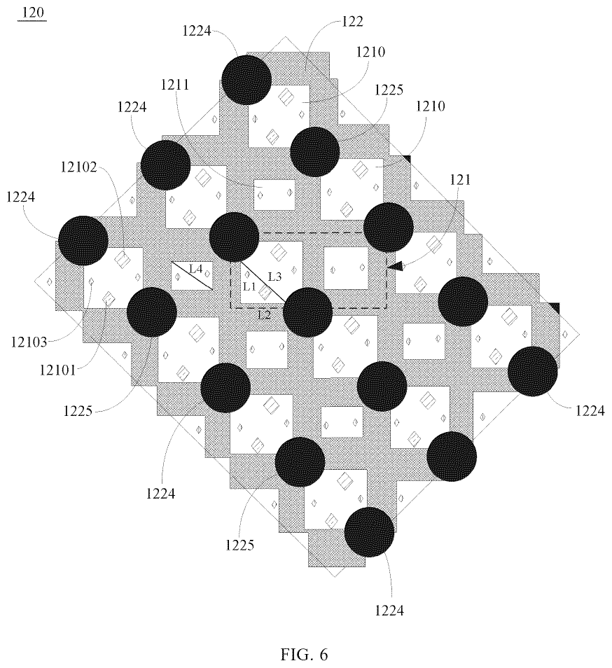

Exemplarily, as shown in FIG. 5, a red display sub-pixel 12101, a blue display sub-pixel 12102, and two green display sub-pixels 12103 are employed in the first region 1210. The red display sub-pixel 12101 and the blue display sub-pixel 12102 are sequentially arranged in a column direction. The two green display sub-pixels 12103 are located in the row direction between the red display sub-pixel 12101 and the blue display sub-pixel 12102, and the two green display sub-pixels 12103 are sequentially spaced apart in the row direction. The sub-pixels in the second region 1211 may be two green display sub-pixels 12103. The arrangement of the sub-pixels in the first region 1210 and the second region 1211 can effectively increase the number of pixels and the pixels per inch of the photosensitive display region 120, so that the pixel difference between the photosensitive display region 120 and the normal display region 110 can be reduced, to make the photosensitive display region 120 and the normal display region 110 balanced, and the color difference between these two regions is reduced, and the PPI of the photosensitive display region 120 is increased, and the light transmissive region 122 can also ensure the light transmission rate of the photosensitive display region 120, ensuring a high transmissive region.

It should be noted that the second region 1211 may also contain other types of display sub-pixels 1110, for example, a red display sub-pixel 12101, a blue display sub-pixel 12102, etc.

In order to ensure the light transmissive rate of the light transmissive region 122, the light transmissive region 122 is provided around the first region 1210 and the second region 1211, and adjacent light transmissive regions 122 are connected to each other.

It is to be understood that as shown in FIG. 4, the first region 1210 and the second region 1211 are formed by surrounding of adjacent light transmissive regions 122, and the display sub-pixels 1110 are formed within the first region 1210 and the second region 1211.

As shown in FIG. 5, the light transmissive region 122 includes a first straight edge 1220 and a second straight edge 1221 parallel to the first direction, and a third straight edge 1222 and a fourth straight edge 1223 parallel to the second direction. The first straight edge 1220 and the second straight edge 1221 are provided parallel to each other and opposite to each other, and the third straight edge 1222 and the fourth straight edge 1223 are provided parallel to each other and opposite to each other. The first direction intersects with the second direction. The first region 1210 is located within the region enclosed by the first straight edge 1220, the second straight edge 1221, the third straight edge 1222 and the fourth straight edge 1223, that is, the first region 1210 is enclosed by the first straight edge 1220, the second straight edge 1221, the third straight edge 1222 and the fourth straight edge 1223. Since the second region 1211 is located among four adjacent first regions 1210, thus the second region 1211 is located within a region enclosed by the first straight edge 1220, the second straight edge 1221, the third straight edge 1222, and the fourth straight edge 1223 in each of the four adjacent light transmissive regions 122, i.e., the four edges of the second region 1211 are formed by four different light transmissive regions 122.

That is, the first region 1210 and the second region 1211 are both surrounded with light transmissive regions 122, which can ensure the transmissive rate of light in the photosensitive display region 120 while increasing the PPI of the photosensitive display region 120, thereby improving the display effect of the photosensitive display region 120.

It is to be noted that the first direction and the second direction may be perpendicular to each other, or form a non-rectangular angle, such as an acute angle, an obtuse angle, etc. As long as it can ensure the PPI of the photosensitive display region 120 while ensuring the high transmissive region.

In the embodiment of the present application, the first direction and the second direction are perpendicular to each other, i.e., the first straight edge 1220 is perpendicular to the third straight edge 1222 and the fourth straight edge 1223, and the second straight edge 1221 is perpendicular to the third straight edge 1222 and the fourth straight edge 1223. The vertical structure makes the arrangement of the first region 1210 and the second region 1211 more tidiness, thereby optimizing the arrangement structure of the sub-pixels in the photosensitive display region 120, and improving the display effect of the photosensitive display region 120.

As shown in FIG. 5, when the first direction and the second direction are perpendicular to each other, two opposite ends of the first straight edge 1220 form two right-angle junctions with the third straight edge 1222 and the fourth straight edge 1223, respectively, and two opposite ends of the second straight edge 1221 also form two right-angle junctions with the third straight edge 1222 and the fourth straight edge 1223, respectively. That is, the first region 1210 includes four right-angle junctions, and accordingly, the second region 1211 is enclosed by the straight edges in the different light transmissive regions 122, and the second region 1211 also includes four right-angle junctions.

### Second Embodiment

The difference between the second embodiment and the first embodiment of the present application is that at least one of the four right-angle junctions in the first region 1210 of the second embodiment is formed with a circular curved surface protruding toward the first region 1210. The circular curved surface with the right-angle can greatly reduce such as photo distortion and diffraction during shooting, so that the visual effect of the shooting picture can be effectively improved.

Optionally, the first region 1210 may include two circular curved surfaces protruding from the first region 1210, and the two circular curved surfaces may be provided at any two right-angle junctions of the first region 1210. The circular curved surfaces may be provided at diagonal right-angle junctions, so that the circular curved surfaces are provided relative to each other and the right-angle junctions are also provided relative to each other. Since the right-angle junctions and the circular curved surface junctions are provided symmetrically, the problems of diffraction and photo distortion can be effectively reduced, and the visual effect of the shooting picture can be improved.

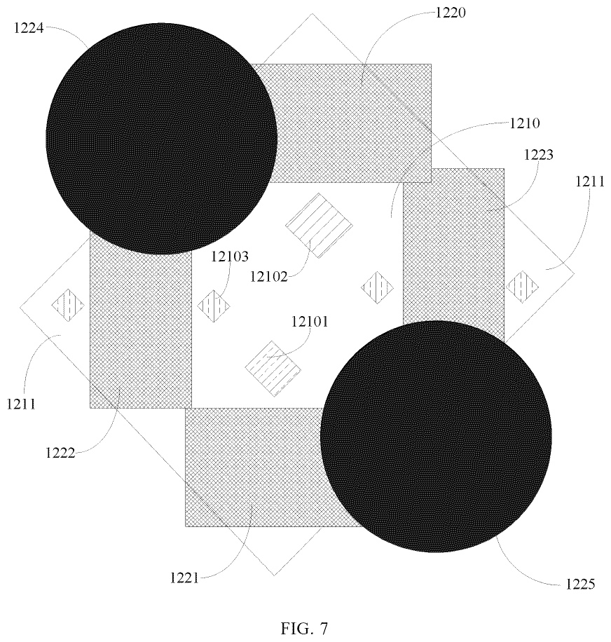

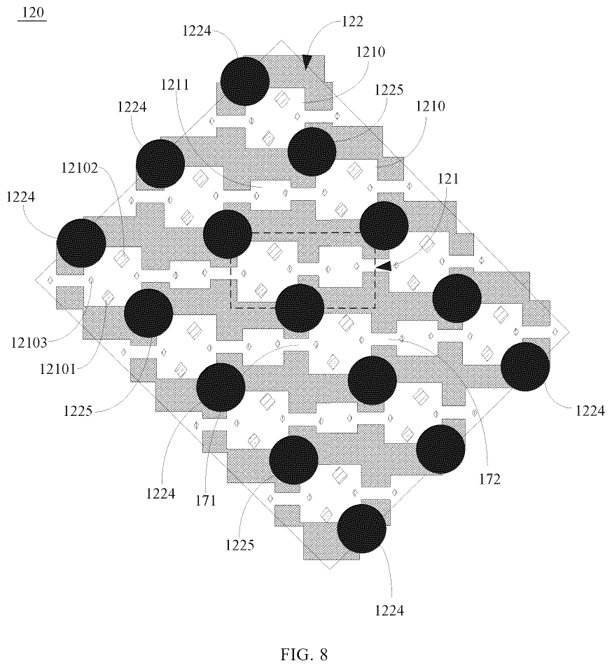

In this embodiment of the present application, as shown in FIGS. 6 and 7, the light transmissive region 122 further includes a first circular region 1224 and a second circular region 1225. The first circular region 1224 and the second circular region 1225 each is provided with a circular curved surface protruding toward the first region 1210, and the first regions 1210 in adjacent rows share the same first circular region 1224 and the second circular region 1225. The first circular region 1224 and the second circular region 1225 are provided at any two of the above four junctions. The first circular region 1224 and the second circular region 1225 increase the area of the high transmissive region, such that the amount of light that can enter the under-screen photosensitive 20 is increased, and thus the brightness of the captured picture is enhanced. In addition, since the first circular region 1224 and the second circular region 1225 are combined with the right-angles, the distortion of the shooting picture is avoided and the diffraction is reduced, thereby improving the visual effect of shooting picture.

It is to be understood that when the boundary of the light transmissive region 122 close to the first region 1210 is circular, the shooting pictures will occur the distortion. When the boundary of the light transmissive region 122 close to the first region 1210 is square, i.e., all right-angle junctions, diffraction will be obvious and affect the visual effect. Therefore, the light transmissive region 122 of the present embodiment close to the boundary of the first region 1210 adopts a combination of circular and square, which can effectively reduce distortion generated by shooting pictures, and reduce diffraction, thereby improving the visual effect of shooting picture.

In this embodiment of the present application, as shown in FIGS. 6 and 7, the first

circular region 1224 and the second circular region 1225 are respectively provided at diagonal corners, the first circular region 1224 is provided at the junction of the first straight edge 1220 and the third straight edge 1222, and the second circular region 1225 is provided at the junction of the second straight edge 1221 and the fourth straight edge 1223. The circular region and the straight angle are provided symmetrically, which can effectively reduce the distortion of the shooting picture and reduce the diffraction, thereby improving the visual effect of shooting picture.

As shown in FIGS. 6 and 7, the first straight edge 1220, the second straight edge 1221, the third straight edge 1222, and the fourth straight edge 1223 in the four adjacent light transmissive regions 122 are respectively provided around the second region 1211. In the first region 1210, a distance from the junction of the second straight edge 1221 and the third straight edge 1222 to the first circular region 1224 is L1 and a distance from the junction of the second straight edge 1221 and the third straight edge 1222 to the second circular region 1225 is L2. A length L3 of a hypotenuse is formed by the distance L1 and the distance L2 is not equal to a length L4 of a diagonal of the second region 1211. The length and width of the second region 1211 are not equal to distances from the right-angle junction in the first region 1210 to the first circular region 1224 and to the second circular region 1225, and they do not overlap completely, which can effectively improve the problem of poor diffraction.

### Third Embodiment

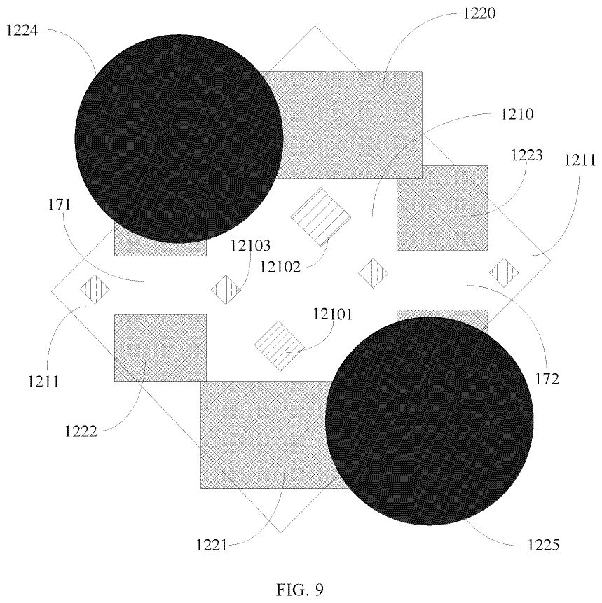

The difference between the third Embodiment of the present application and the second Embodiment is that, as shown in FIGS. 8 and 9, the third straight edge 1222 and the fourth straight edge 1223 are segmented, and the metal-routing on the driving circuit layer 150 can be routed from the partitions of the third straight edge 1222 and the fourth straight edge 1223. Since the third straight edge 1222 and the fourth straight edge 1223 are provided at intervals sequentially in the row direction, and the partitions of the third straight edge 1222 and the fourth straight edge 1223 are located in the same row, it is possible to ensure that the metal-routing is extended in the row direction, such that the metal-routing has minimum bends, a lower resistance value, and the process is optimal, and it is also possible to control the size of this partition according to the width of the metal-routing.

It can be understood that since the number of green sub-pixels in the normal display region 110 and the photosensitive display region 120 is large, the more metal-routing is required, and since the green sub-pixels are sequentially spaced apart in the same row direction, the partition is provided at the third straight edge 1222 and the fourth straight edge 1223 in order to minimize the bending of the metal-routing.

Exemplarily, as shown in FIG. 9, the third straight edge 1222 includes a first segment and a second segment spaced apart from each other, one end of the first segment is connected to the first circular region 1224, and another end of the first segment extends toward the second straight edge 1221. One end of the second segment is connected to the second straight edge 1221, and another end of the second segment is extended toward the first circular region 1224. A first partition 171 is provided between the first segment and the second segment, the first partition 171 is provided with a first black matrix and in the same row as the green sub-pixels. The fourth straight edge 1223 includes a third segment and a fourth segment spaced apart from each other, one end of the third segment is connected to the first straight edge 1220, and another end of the third segment is extended toward the second straight edge 1221. One end of the fourth segment is connected to the second circular region 1225 and another end of the fourth segment extends toward the first straight edge 1220. A second partition 172 is provided between the third segment and the fourth segment, the second partition 172 is provided with a first black matrix and in the same row as green sub-pixels. In the photosensitive display region 120, the first partition 171 and the second partition 172 are provided in the same row, and the metal-routing may be provided in the first partition 171 and the second partition 172 to avoid bending of the metal-routing, thereby reducing the resistance value of the metal-routing, such that the layout of the metal-routing is optimized.

It is to be understood that the first partition 171 and the second partition 172 may determine their partition distances according to the size of the metal-routing.

### Fourth Embodiment

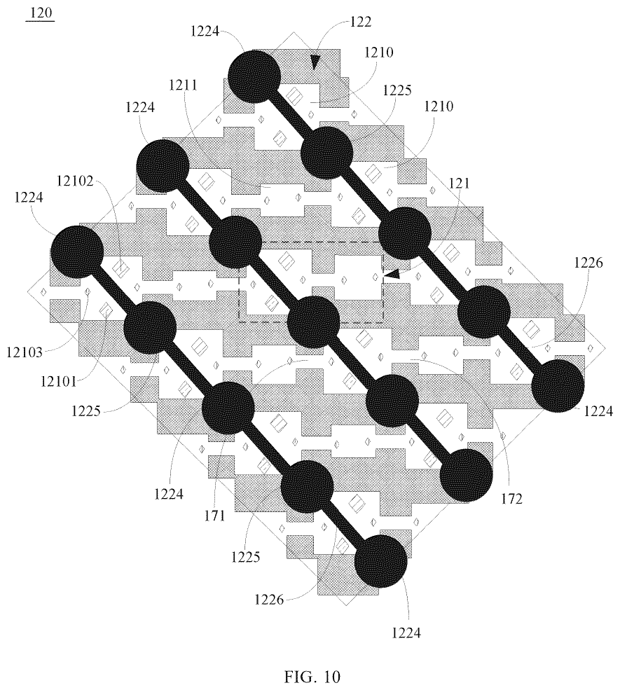

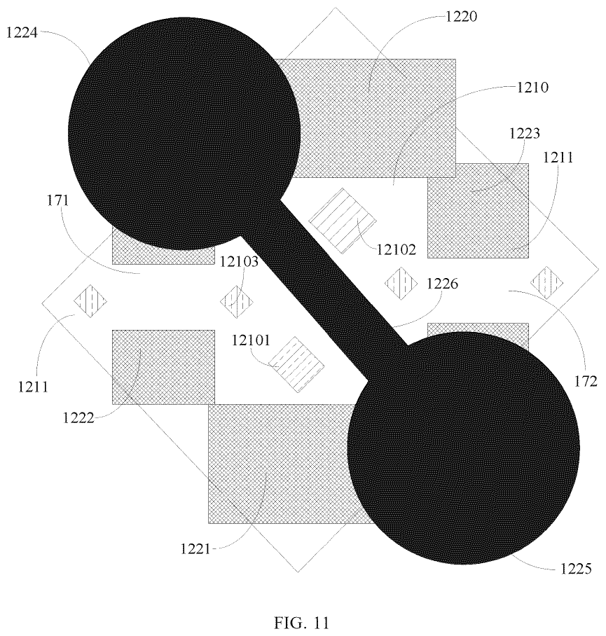

The difference between the fourth embodiment of the present application and the second embodiment or third embodiment is that, as shown in FIGS. 10 and 11, the light transmissive region 122 further includes a connection region 1226, and one end of the connection region 1226 is connected to the first circular region 1224 and another end of the connection region 1226 is connected to the second circular region 1225. That is, the diagonal line of the connection region 1226 connects the first circular region 1224 to the second circular region 1225, thereby increasing the light transmissive area of the light transmissive region 122, so that more light enters the photosensitive element 20, and the brightness and clarity of the shooting picture can be increased.

It is worth mentioning that the connection region 1226 should be provided at intervals with the sub-pixels in the first region 1210 to avoid affecting the display effect of the photosensitive display region 120.

In addition, the photosensitive display region 120 may have different display modes, which can be matched with the integrated circuit signals to optimize the display visual effect. Exemplarily, the red sub-pixels, the green sub-pixels, and the blue sub-pixels in the first region 1210 are controlled by the integrated circuit signals to be displayed. It is also possible to control the blue sub-pixels in the first region 1210, the green sub-pixels in the second region 1211, and the red sub-pixels in another first region 1210 by the integrated circuit signals to achieve a different display from the above display.

### Fifth Embodiment

The fifth embodiment provides a display device 1, as shown in FIG. 3, the display device 1 includes the display panel 10 mentioned in the first embodiment, the second embodiment, the third embodiment, or the fourth embodiment, and a photosensitive element 20 corresponding to the photosensitive display region 120. Since the photosensitive display region 120 in the first embodiment, the second embodiment, the third embodiment, or the fourth embodiment in this embodiment is used, the shooting brightness of the photosensitive element 20 can be ensured while increasing the PPI of the photosensitive display region 120.

In the description of this specification, the description with reference to the terms “some embodiments”, “exemplarily”, etc. means that the specific features, structures, materials, or characteristics described in conjunction with the embodiment or example are included in at least one embodiment or example of the present application. In this specification, schematic expressions of the above terms need not be directed to the same embodiment or example. Moreover, the specific features, structures, materials, or characteristics described may be combined in any one or more embodiments or examples in a suitable manner. Moreover, without contradicting each other, those skilled in the art may combine and combine different embodiments or examples and features of different embodiments or examples described in this specification.

Although the embodiments of the present application are shown and described above, it is understood that the above embodiments are exemplary and cannot be construed as a limitation of the present application, and that those skilled in the art may make changes, modifications, substitutions and variations of the above embodiments within the scope of the present application, so that any changes or modifications made in accordance with the claims and the specification of the present application shall fall within the scope of the present application.

What is claimed is:

1. A display panel, comprising a normal display region and a photosensitive display region corresponding to a photosensitive element, wherein the normal display region is provided around the photosensitive display region, the normal display region comprises a plurality of pixel units arranged in an array, and each pixel unit comprises a plurality of display sub-pixels;
wherein the photosensitive display region comprises a display pixel region and a light transmissive region, and the light transmissive region is arranged at intervals with the display pixel region;
wherein the display pixel region comprises a first region and a second region, the light transmissive region is provided at a periphery of the first region and a periphery of the second region, and the first region and the second region are spaced apart in a row direction sequentially; and
wherein pixels in at least one of the first region and the second region are arranged in the same way as display sub-pixels in each of the plurality of pixel units in the normal display region.

2. The display panel according to claim 1, wherein:
the pixels in the first region are arranged in the same way as the display sub-pixels in each of the plurality of pixel units in the normal display region; and
the display sub-pixels in the second region have the same color.

3. The display panel according to claim 2, wherein the light transmissive region comprises a first straight edge and a second straight edge parallel to a first direction, and a third straight edge and a fourth straight edge parallel to a second direction;
wherein the first straight edge is opposite to the second straight edge, the third straight edge is opposite to the fourth straight edge, and the first direction is intersected with the second direction; and
the first straight edge, the second straight edge, the third straight edge and the fourth straight edge are provided around the first region.

4. The display panel according to claim 3, wherein the first direction is perpendicular to the second direction, and the first straight edge forms two first junctions with the third straight edge and the fourth straight edge, and the second straight edge forms two second junctions with the third straight edge and the fourth straight edge; and
a circular curved surface protruding toward the first region is formed on at least one of the two first junctions and the two second junctions.

5. The display panel according to claim 4, wherein the light transmissive region further comprises a first circular region and a second circular region, each of the first circular region and the second circular region is provided with the circular curved surface protruding toward the first region, and the first circular region and the second circular region are provided at any two of the two first junctions and the two second junctions; and
adjacent first regions share the first circular region or the second circular region.

6. The display panel according to claim 5, wherein the first circular region and the second circular region are provided diagonally, the first circular region is provided at a first junction of the first straight edge and the third straight edge, and the second circular region is provided at a second junction of the second straight edge and the fourth straight edge.

7. The display panel according to claim 6, wherein the first straight edge, the second straight edge, the third straight edge and the fourth straight edge of four adjacent light transmissive regions are provided around the second region, respectively; and
a length of a hypotenuse formed by a distance from the second junction of the second straight edge and the third straight edge to the first circular region and a distance from the second junction of the second straight edge and the third straight edge to the second circular region is not equal to a length of a diagonal of the second region.

8. The display panel according to claim 5, wherein the third straight edge comprises a first segment and a second segment spaced apart from each other, wherein one end of the first segment is connected to the first circular region, one end of the second segment is connected to the second straight edge, and a first partition is provided between the first segment and the second segment; and
the fourth straight edge comprises a third segment and a fourth segment spaced apart from each other, wherein one end of the third segment is connected to the first straight edge, one end of the fourth segment is connected to the second circular region, and a second partition is provided between the third segment and the fourth segment;
wherein the first partition and the second partition are provided in the same row.

9. The display panel according to claim 5, wherein the light transmissive region further comprises a connection region, one end of the connection region is connected to the first circular region and another end of the connection region is connected to the second circular region, and the connection region is provided at intervals with sub-pixels in the first region.

10. The display panel according to claim 1, wherein each display sub-pixel comprises a display light emitting diode, and the display light emitting diode comprises a display light emitting portion formed on an organic light emitting function layer, and each display light emitting portion emits light of different colors;
wherein the display light emitting diode further comprises a display anode and a display cathode, the display anode is provided on a side of the display light emitting portion close to a substrate, and the display cathode is provided on a side of the display light emitting portion away from the substrate.

11. The display panel according to claim 10, wherein the display anodes of each display light emitting diode in the display panel are arranged at intervals from one another, to make each display light emitting diode be independently driven, and the display cathodes of each display light emitting diode is connected to each other to form a whole planar electrode.

12. The display panel according to claim 10, wherein the display panel further comprises the substrate, and a driving circuit layer, a flattening layer and a pixel definition layer formed sequentially on the substrate;
wherein the display anode comprises a first conductive layer formed on a side of the flattening layer away from the driving circuit layer and located between the flattening layer and the pixel definition layer.

13. The display panel according to claim 12, wherein a pixel opening exposes a middle region of the first conductive layer, and the display light emitting portion is provided within the pixel opening and is in contact with the middle region of the first conductive layer.

14. A display device, comprising a display panel and a photosensitive element, wherein the photosensitive element corresponds to a photosensitive display region;
wherein the display panel comprises a normal display region and the photosensitive display region corresponding to the photosensitive element, the normal display region is provided around the photosensitive display region, and the normal display region comprises a plurality of pixel units arranged in an array, and each pixel unit comprises a plurality of display sub-pixels;
wherein the photosensitive display region comprises a display pixel region and a light transmissive region, and the light transmissive region is arranged at intervals with the display pixel region;
wherein the display pixel region comprises a first region and a second region, the light transmissive region is provided at a periphery of the first region and a periphery of the second region, and the first region and the second region are spaced apart in a row direction sequentially; and
wherein pixels in at least one of the first region and the second region are arranged in the same way as display sub-pixels in each of the plurality of pixel units in the normal display region.

15. The display device according to claim 14, wherein:
the pixels in the first region are arranged in the same way as the display sub-pixels in each of the plurality of pixel units in the normal display region; and
the display sub-pixels in the second region have a same color.

16. The display device according to claim 15, wherein the light transmissive region comprises a first straight edge and a second straight edge parallel to a first direction, and a third straight edge and a fourth straight edge parallel to a second direction;
wherein the first straight edge is opposite to the second straight edge, the third straight edge is opposite to the fourth straight edge, and the first direction is intersected with the second direction; and
the first straight edge, the second straight edge, the third straight edge and the fourth straight edge are provided around the first region.

17. The display device according to claim 16, wherein the first direction is perpendicular to the second direction, and the first straight edge forms two first junctions with the third straight edge and the fourth straight edge, and the second straight edge forms two second junctions with the third straight edge and the fourth straight edge; and
a circular curved surface protruding toward the first region is formed on at least one of the two first junctions and the two second junctions.

18. The display device according to claim 17, wherein the light transmissive region further comprises a first circular region and a second circular region, each of the first circular region and the second circular region is provided with the circular curved surface protruding toward the first region, and the first circular region and the second circular region are provided at any two of the two first junctions and the two second junctions; and
adjacent first regions share the first circular region or the second circular region.

19. The display device according to claim 18, wherein the first circular region and the second circular region are provided diagonally, the first circular region is provided at a first junction of the first straight edge and the third straight edge, and the second circular region is provided at a second junction of the second straight edge and the fourth straight edge.

20. The display device according to claim 19, wherein the first straight edge, the second straight edge, the third straight edge and the fourth straight edge of four adjacent light transmissive regions are provided around the second region, respectively; and
a length of a hypotenuse formed by a distance from the second junction of the second straight edge and the third straight edge to the first circular region and a distance from the second junction of the second straight edge and the third straight edge to the second circular region is not equal to a length of a diagonal of the second region.
